(19) United States
(12) Patent Application Publication
(10) Pub. No.: US 2014/0063784 A1
(43) Pub. Date: Mar. 6, 2014

(54) Multi-Layered Electronic Device Cover

(71) Applicant: Gregory P. Muiter, Wexford, PA (US)

(72) Inventor: Gregory P. Muiter, Wexford, PA (US)

(21) Appl. No.: 13/597,660

(22) Filed: Aug. 29, 2012

(51) Int. Cl. F21V 11/08; F21V 13/02; G09F 13/04; H05K 13/00

(52) U.S. Cl. 362/97.1; 29/592.1; 362/277

(57) ABSTRACT

A multi-layered decorative electronic device cover that fastens to an electronic device, such as the outer screen of a laptop computer. The electronic device cover is sufficiently rigid to protect the laptop, yet also transparent enough to allow the light form a light source on the laptop to pass through. A passive light can passes through the translucent material of the cover. An active light can pass through a decoratively designed hole in the cover. The cover includes a first layer that attaches directly to the laptop. A second layer may attach to the first layer, and a third layer can also overlay the second layer. Each layer can have its own unique functional and decorative characteristics. Each layer can include a lens for taking pictures, a screen for displaying images, a prism. An optical fiber can also carry light from the laptop's light source to each layer.

### FEDERALLY SPONSORED RESEARCH OR DEVELOPMENT

Not applicable.

### REFERENCE TO SEQUENCE LISTING, A TABLE, OR A COMPUTER LISTING APPENDIX

Not applicable.

### COPYRIGHT NOTICE

A portion of the disclosure of this patent document contains material that is subject to copyright protection. The copyright owner has no objection to the facsimile reproduction by anyone of the patent document or patent disclosure as it appears in the Patent and Trademark Office, patent file or records, but otherwise reserves all copyright rights whatsoever.

### FIELD OF THE INVENTION

One or more embodiments of the invention generally relate to covers. More particularly, one or more embodiments of the invention relate to electronic device covers.

### BACKGROUND OF THE INVENTION

The following background information may present examples of specific aspects of the prior art (e.g., without limitation, approaches, facts, or common wisdom) that, while expected to be helpful to further educate the reader as to additional aspects of the prior art, is not to be construed as limiting the present invention, or any embodiments thereof, to anything stated or implied therein or inferred thereupon.

The following is an example of a specific aspect in the prior art that, while expected to be helpful to further educate the reader as to additional aspects of the prior art, is not to be construed as limiting the present invention, or any embodiments thereof, to anything stated or implied therein or inferred thereupon. By way of educational background, another aspect of the prior art generally useful to be aware of is that laptop covers are usually used to protect the internal components of a laptop. Often, laptop covers are used to protect laptop screens. Sometimes a laptop may have an exterior light source. Typically this light source is blocked, at least partially, by a laptop cover.

In view of the foregoing, it is clear that these traditional techniques are not perfect and leave room for more optimal approaches.

### BRIEF DESCRIPTION OF THE DRAWINGS

The present invention is illustrated by way of example, and not by way of limitation, in the figures of the accompanying drawings and in which like reference numerals refer to similar elements and in which:

FIG. 1 illustrates an exemplary electronic device cover, in accordance with an embodiment of the present invention;

FIG. 2 illustrates an exemplary first layer of an exemplary electronic device cover, in accordance with an embodiment of the present invention; and

FIG. 3 illustrates an exemplary second layer of an exemplary electronic device cover, in accordance with an embodiment of the present invention;

FIG. 4 illustrates an exemplary third layer of an exemplary electronic device cover, in accordance with an embodiment of the present invention; and

FIG. 5 illustrates a diagram of an exemplary light source passing through an exemplary first layer aperture, in accordance with an embodiment of the present invention.

Unless otherwise indicated illustrations in the figures are not necessarily drawn to scale.

### DETAILED DESCRIPTION OF SOME EMBODIMENTS

Embodiments of the present invention are best understood by reference to the detailed figures and description set forth herein.

Embodiments of the invention are discussed below with reference to the Figures. However, those skilled in the art will readily appreciate that the detailed description given herein with respect to these figures is for explanatory purposes as the invention extends beyond these limited embodiments. For example, it should be appreciated that those skilled in the art will, in light of the teachings of the present invention, recognize a multiplicity of alternate and suitable approaches, depending upon the needs of the particular application, to implement the functionality of any given detail described herein, beyond the particular implementation choices in the following embodiments described and shown. That is, there are numerous modifications and variations of the invention that are too numerous to be listed but that all fit within the scope of the invention. Also, singular words should be read as plural and vice versa and masculine as feminine and vice versa, where appropriate, and alternative embodiments do not necessarily imply that the two are mutually exclusive.

It is to be further understood that the present invention is not limited to the particular methodology, compounds, materials, manufacturing techniques, uses, and applications, described herein, as these may vary. It is also to be understood that the terminology used herein is used for the purpose of describing particular embodiments only, and is not intended to limit the scope of the present invention. It must be noted that as used herein and in the appended claims, the singular forms “a,” “an,” and “the” include the plural reference unless the context clearly dictates otherwise. Thus, for example, a reference to “an element” is a reference to one or more elements and includes equivalents thereof known to those skilled in the art. Similarly, for another example, a reference to “a step” or “a means” is a reference to one or more steps or means and may include sub-steps and subservient means. All conjunctions used are to be understood in the most inclusive sense possible. Thus, the word “or” should be understood as having the definition of a logical “or” rather than that of a logical “exclusive or” unless the context clearly necessitates otherwise. Structures described herein are to be understood also to refer to functional equivalents of such structures. Language that may be construed to express approximation should be so understood unless the context clearly dictates otherwise.

Unless defined otherwise, all technical and scientific terms used herein have the same meanings as commonly understood by one of ordinary skill in the art to which this invention belongs. Preferred methods, techniques, devices, and materials are described, although any methods, techniques, devices, or materials similar or equivalent to those described herein may be used in the practice or testing of the present invention. Structures described herein are to be understood also to refer to functional equivalents of such structures. The present invention will now be described in detail with reference to embodiments thereof as illustrated in the accompanying drawings.

From reading the present disclosure, other variations and modifications will be apparent to persons skilled in the art. Such variations and modifications may involve equivalent and other features which are already known in the art, and which may be used instead of or in addition to features already described herein.

Although Claims have been formulated in this Application to particular combinations of features, it should be understood that the scope of the disclosure of the present invention also includes any novel feature or any novel combination of features disclosed herein either explicitly or implicitly or any generalization thereof, whether or not it relates to the same invention as presently claimed in any Claim and whether or not it mitigates any or all of the same technical problems as does the present invention.

Features which are described in the context of separate embodiments may also be provided in combination in a single embodiment. Conversely, various features which are, for brevity, described in the context of a single embodiment, may also be provided separately or in any suitable subcombination. The Applicants hereby give notice that new Claims may be formulated to such features and/or combinations of such features during the prosecution of the present Application or of any further Application derived therefrom.

References to “one embodiment,” “an embodiment,” “example embodiment,” “various embodiments,” etc., may indicate that the embodiment(s) of the invention so described may include a particular feature, structure, or characteristic, but not every embodiment necessarily includes the particular feature, structure, or characteristic. Further, repeated use of the phrase “in one embodiment,” or “in an exemplary embodiment,” do not necessarily refer to the same embodiment, although they may.

As is well known to those skilled in the art many careful considerations and compromises typically must be made when designing for the optimal manufacture of a commercial implementation any system, and in particular, the embodiments of the present invention. A commercial implementation in accordance with the spirit and teachings of the present invention may configured according to the needs of the particular application, whereby any aspect(s), feature(s), function(s), result(s), component(s), approach(es), or step(s) of the teachings related to any described embodiment of the present invention may be suitably omitted, included, adapted, mixed and matched, or improved and/or optimized by those skilled in the art, using their average skills and known techniques, to achieve the desired implementation that addresses the needs of the particular application.

In the following description and claims, the terms “coupled” and “connected,” along with their derivatives, may be used. It should be understood that these terms are not intended as synonyms for each other. Rather, in particular embodiments, “connected” may be used to indicate that two or more elements are in direct physical or electrical contact with each other. “Coupled” may mean that two or more elements are in direct physical or electrical contact. However, “coupled” may also mean that two or more elements are not in direct contact with each other, but yet still cooperate or interact with each other.

A “computer” may refer to one or more apparatus and/or one or more systems that are capable of accepting a structured input, processing the structured input according to prescribed rules, and producing results of the processing as output. Examples of a computer may include: a computer; a stationary and/or portable computer; a computer having a single processor, multiple processors, or multi-core processors, which may operate in parallel and/or not in parallel; a general purpose computer; a supercomputer; a mainframe; a super mini-computer; a mini-computer; a workstation; a micro-computer; a server; a client; an interactive television; a web appliance; a telecommunications device with internet access; a hybrid combination of a computer and an interactive television; a portable computer; a tablet personal computer (PC); a personal digital assistant (PDA); a portable telephone; application-specific hardware to emulate a computer and/or software, such as, for example, a digital signal processor (DSP), a field-programmable gate array (FPGA), an application specific integrated circuit (ASIC), an application specific instruction-set processor (ASIP), a chip, chips, a system on a chip, or a chip set; a data acquisition device; an optical computer; a quantum computer; a biological computer; and generally, an apparatus that may accept data, process data according to one or more stored software programs, generate results, and typically include input, output, storage, arithmetic, logic, and control units.

“Software” may refer to prescribed rules to operate a computer. Examples of software may include: code segments in one or more computer-readable languages; graphical and or/textual instructions; applets; pre-compiled code; interpreted code; compiled code; and computer programs.

A “computer-readable medium” may refer to any storage device used for storing data accessible by a computer. Examples of a computer-readable medium may include: a magnetic hard disk; a floppy disk; an optical disk, such as a CD-ROM and a DVD; a magnetic tape; a flash memory; a memory chip; and/or other types of media that can store machine-readable instructions thereon.

A “computer system” may refer to a system having one or more computers, where each computer may include a computer-readable medium embodying software to operate the computer or one or more of its components. Examples of a computer system may include: a distributed computer system for processing information via computer systems linked by a network; two or more computer systems connected together via a network for transmitting and/or receiving information between the computer systems; a computer system including two or more processors within a single computer; and one or more apparatuses and/or one or more systems that may accept data, may process data in accordance with one or more stored software programs, may generate results, and typically may include input, output, storage, arithmetic, logic, and control units.

A “network” may refer to a number of computers and associated devices that may be connected by communication facilities. A network may involve permanent connections such as cables or temporary connections such as those made through telephone or other communication links. A network may further include hard-wired connections (e.g., coaxial cable, twisted pair, optical fiber, waveguides, etc.) and/or wireless connections (e.g., radio frequency waveforms, free-space optical waveforms, acoustic waveforms, etc.). Examples of a network may include: an internet, such as the Internet; an intranet; a local area network (LAN); a wide area network (WAN); and a combination of networks, such as an internet and an intranet.

Exemplary networks may operate with any of a number of protocols, such as Internet protocol (IP), asynchronous transfer mode (ATM), and/or synchronous optical network (SONET), user datagram protocol (UDP), IEEE 802.x, etc.

Embodiments of the present invention may include apparatuses for performing the operations disclosed herein. An apparatus may be specially constructed for the desired purposes, or it may comprise a general-purpose device selectively activated or reconfigured by a program stored in the device.

Embodiments of the invention may also be implemented in one or a combination of hardware, firmware, and software. They may be implemented as instructions stored on a machine-readable medium, which may be read and executed by a computing platform to perform the operations described herein.

In the following description and claims, the terms “computer program medium” and “computer readable medium” may be used to generally refer to media such as, but not limited to, removable storage drives, a hard disk installed in hard disk drive, and the like. These computer program products may provide software to a computer system. Embodiments of the invention may be directed to such computer program products.

An algorithm is here, and generally, considered to be a self-consistent sequence of acts or operations leading to a desired result. These include physical manipulations of physical quantities. Usually, though not necessarily, these quantities take the form of electrical or magnetic signals capable of being stored, transferred, combined, compared, and otherwise manipulated. It has proven convenient at times, principally for reasons of common usage, to refer to these signals as bits, values, elements, symbols, characters, terms, numbers or the like. It should be understood, however, that all of these and similar terms are to be associated with the appropriate physical quantities and are merely convenient labels applied to these quantities.

Unless specifically stated otherwise, and as may be apparent from the following description and claims, it should be appreciated that throughout the specification descriptions utilizing terms such as “processing,” “computing,” “calculating,” “determining,” or the like, refer to the action and/or processes of a computer or computing system, or similar electronic computing device, that manipulate and/or transform data represented as physical, such as electronic, quantities within the computing system's registers and/or memories into other data similarly represented as physical quantities within the computing system's memories, registers or other such information storage, transmission or display devices.

In a similar manner, the term “processor” may refer to any device or portion of a device that processes electronic data from registers and/or memory to transform that electronic data into other electronic data that may be stored in registers and/or memory. A “computing platform” may comprise one or more processors.

A non-transitory computer readable medium includes, but is not limited to, a hard drive, compact disc, flash memory, volatile memory, random access memory, magnetic memory, optical memory, semiconductor based memory, phase change memory, optical memory, periodically refreshed memory, and the like; however, the non-transitory computer readable medium does not include a pure transitory signal per se; i.e., where the medium itself is transitory.

It is to be understood that any exact measurements/dimensions or particular construction materials indicated herein are solely provided as examples of suitable configurations and are not intended to be limiting in any way. Depending on the needs of the particular application, those skilled in the art will readily recognize, in light of the following teachings, a multiplicity of suitable alternative implementation details.

The present invention will now be described in detail with reference to embodiments thereof as illustrated in the accompanying drawings.

There are various types of electronic device covers 100 that may be provided by preferred embodiments of the present invention. For example, without limitation, the electronic device cover may provide a multi-layered decorative electronic device cover that fastens to an electronic device, such as the outer screen of a laptop computer or a smart phone. The electronic device cover is sufficiently rigid to protect the electronic device, yet also transparent enough to allow a light form a light source on the electronic device to pass through. In some embodiments, a passive light may pass through the translucent material of the electronic device cover. In other embodiments, an active light may pass through a decoratively designed aperture in the electronic device cover. In some embodiments, the electronic device cover may include a first layer that attaches directly to the electronic device. A second layer may attach to the first layer, and a third layer may also overlay the second layer. Each layer may have its own unique functional and decorative characteristics. Each layer may include a lens for taking pictures, a screen for displaying images, a prism. An optical fiber can also carry light from the laptop's light source to each layer.

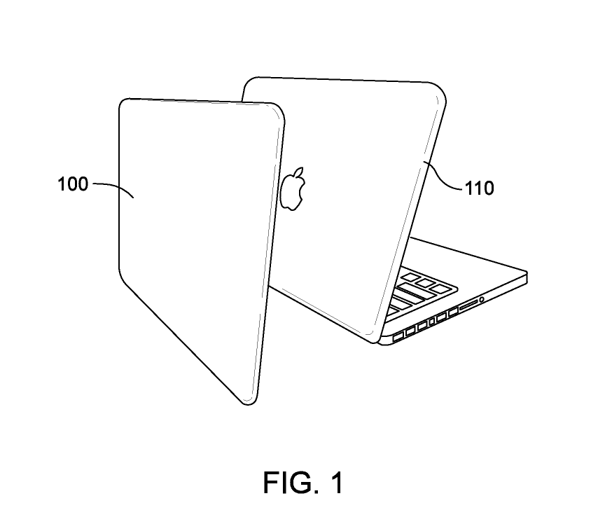

FIG. 1 illustrates an exemplary electronic device cover 100, in accordance with an embodiment of the present invention. In some embodiments, the cover may be flexible. In at least one embodiment of the present invention, the cover may be solid. In at least one embodiment of the present invention, the cover may be configured to protect an electronic device 110. In some embodiments, the electronic device may include, without limitation, a laptop, a cellular phone, a smart phone, an iPad, an iPod, a television, and a radio. In some embodiments, the cover may overlay the exterior of the screen of a laptop computer. In some embodiments, the electronic device cover may include a first layer 105. The first layer may include a first layer mounting surface 106 for engaging the electronic device. The first layer mounting surface may be joined to the electronic device 110 in some embodiments. Those skilled in the art, in light of the present teachings, will recognize that the user or viewer of the product will never see the first layer mounting surface except during installation and uninstallation. Suitable electronic devices include, but are not limited to, a laptop, a monitor, a notebook, a phone, a smartphone, an electronic reader, a tablet, and a combination thereof. Suitable joining mechanisms for joining the first layer 105 to the electronic device 110 include, but are not limited to, a strap, a snap, a buckle, a non-elastic strap, a hook and loop material, a clip, a magnet, an adhesive, and a combination thereof. In some embodiments, the first layer 105 may be removably joined to the electronic device 110. In at least one embodiment of the present invention, the first layer 105 may be at least partially translucent material operable to diffuse the light from the light source. In some embodiments, the first layer 105 may be configured to glow in the dark. Suitable materials for the first layer 105 include, but are not limited to, plastic, gel, rubber, light diffusing plastic, and combinations thereof The first layer may include various decorative features, including, without limitation, various colors, various textures, designs, text, logos, and shapes. However, in one alternative embodiment, the first layer may include a solid material, not penetrable by a passive light source, nor transparent. In yet another alternative embodiment, the first layer may include an independent power source for powering an audio member. The audio member may work independently from, or in conjunction with the electronic device.

In some embodiments, the electronic device 110 may include a light source 115. In at least one embodiment of the present invention, the light source 115 may be on an outer surface of the electronic device 110. Light from the light source 115 may at least partially pass through the first layer 105 to the ambient environment in some embodiments. In at least one embodiment of the present invention, the first layer may be configured to alter a color of the light from the light source 115. Suitable types of light include, but are not limited to active light and passive light. Those skilled in the art, in light of the present teachings, will recognize that passive light may be generated from the laptop or other source while active light could include any type of power light source be it LED, incandescent, fluorescent, bioluminescence or any yet to be discovered light generating source.

In some embodiments, the first layer 105 may include a first layer aperture 120. In at least one embodiment of the present invention, the first layer aperture 120 may be configured to allow light from the light source 115 to at least partially pass through the first layer 105 to the ambient environment. In one embodiment, the light source and the first layer aperture have a similar size and dimension. Suitable shapes for the first layer aperture include, but are not limited to, an apple, a circle, a square, an emoticon a corporate approved logo, user-submitted design, any conceivable shape(s) and a combination thereof

In at least one embodiment of the present invention, the cover 100 may include a first dimension 125. A suitable range for the first dimension includes, but is not limited to approximately 9 inches. In some embodiments, the cover 100 may include a second dimension 130. A suitable range for the second dimension includes, but is not limited to approximately 14 inches. In at least one embodiment of the present invention, the cover 100 may include a thickness. A suitable range for the thickness includes, but is not limited to less than ½ inch.

In one alternative embodiment, the first layer may include a first layer processor that processes independently of the electronic device. The first layer processor may power a second light source that emits light from the first layer. The light from the electronic device and the light from the first layer may then work in conjunction to enhance the decorative aspects of the electronic device cover. In yet another alternative embodiment, the first layer processor may edit a video or audio clip that transmits from the electronic device.

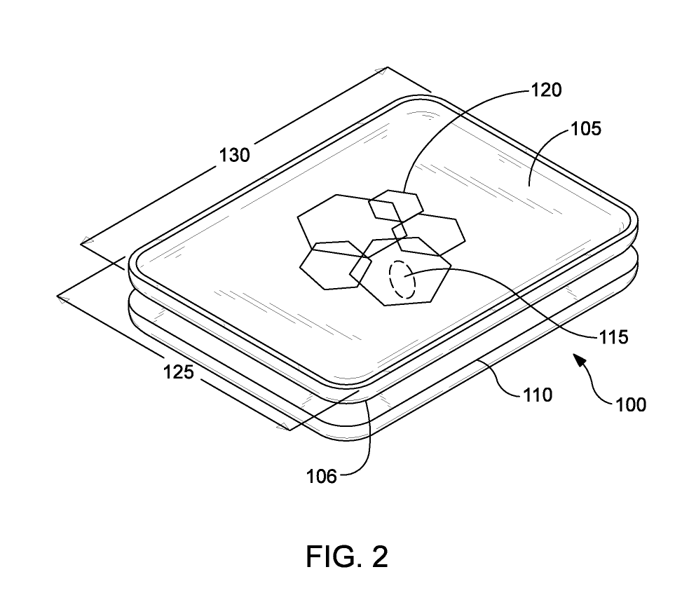

FIG. 2 illustrates an exemplary first layer of an exemplary electronic device cover, in accordance with an embodiment of the present invention. In some embodiments, a second layer 235 may be provided. In at least one embodiment of the present invention, the second layer may be joined to the first layer 205. Suitable joining mechanisms for joining the second layer 235 to the first layer 105 include, but are not limited to, a strap, a snap, a buckle, a non-elastic strap, a hook and loop material, a clip, a magnet, an adhesive or a single but staged layers of plastic injection molding and a combination thereof.

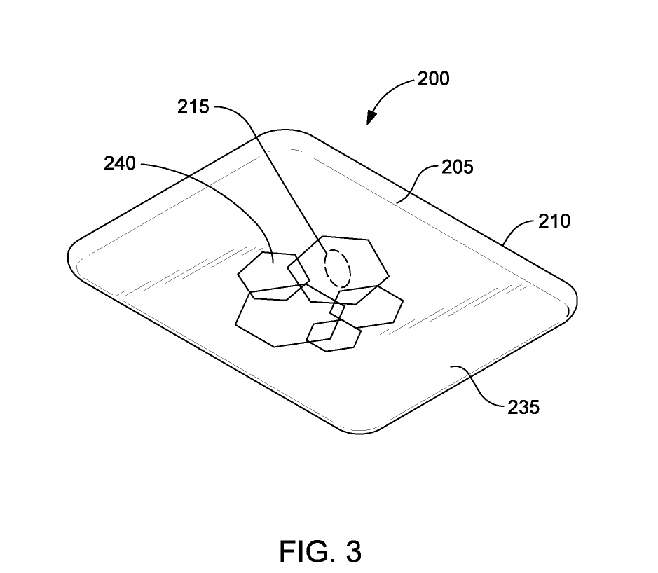

FIG. 3 illustrates an exemplary second layer of an exemplary electronic device cover, in accordance with an embodiment of the present invention. In some embodiments, the second layer 235 may be removably joined to the first layer 205. The second layer may include a second layer mounting surface 236 for engaging the first layer. In at least one embodiment of the present invention, the second layer 235 may be solid material and opaque. In some embodiments, the second layer 235 may be configured to glow in the dark. Suitable materials for the second layer 235 include, but are not limited to, aluminum, plastic, gel, rubber, light diffusing plastic and combinations thereof. In one alternative embodiment, the first layer may create synergy with the second layer to enhance the function and decorative aspects of the electronic device. For example, without limitation, the first layer may include a red translucent material, and the second layer may include a yellow translucent material, whereby an orange light emits from the electronic device cover. Another alternative example of synergy between the layers may include a prism in the first layer that breaks the light up into a multiplicity of spectral colors, so that a lens in the second layer aperture may directionally orient the spectral colors to create a decorative light show.

In some embodiments, the second layer 235 may include a second layer aperture 240. In at least one embodiment of the present invention, the second layer aperture 240 may be aligned, at least partially, with the aperture. The second layer aperture 240 may allow light from the light source 215 to at least partially pass through the second layer 235 to the ambient environment. Suitable shapes for the second layer aperture 240 include, but are not limited to, an apple, a circle, a square, an emoticon, a corporate approved logo, user-submitted design, any conceivable shape(s) and a combination thereof.

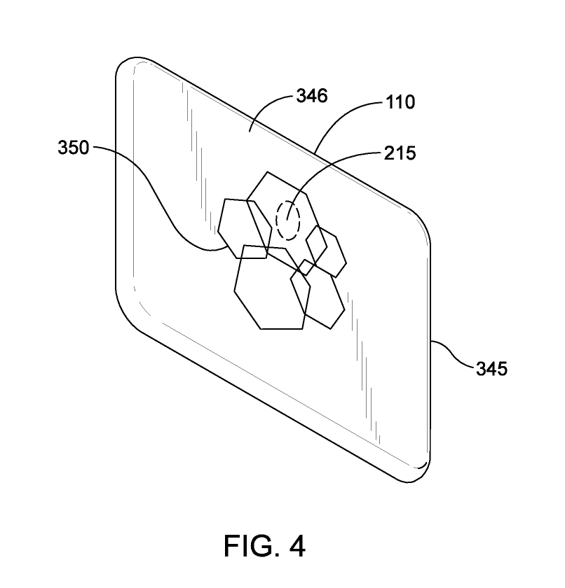

FIG. 4 illustrates an exemplary third layer of an exemplary electronic device cover, in accordance with an embodiment of the present invention. In some embodiments, a third layer 345 may be provided. In at least one embodiment of the present invention, the third layer may be joined to the second layer 235. The third layer may include a third layer mounting surface 346 for engaging the second layer. Suitable joining mechanisms for joining the third layer to the second layer 235 may include, but are not limited to, a strap, a snap, a buckle, a non-elastic strap, a hook and loop material, a clip, a magnet, an adhesive, and a combination thereof

In some embodiments, the third layer may be removably joined to the second layer 235. In at least one embodiment of the present invention, the third layer may be an at least partially translucent material. In some embodiments, the third layer may be configured to glow in the dark. Suitable materials for the third layer include, but are not limited to, plastic, gel, rubber, a single but staged layers of plastic injection molding and and combinations thereof.

In some embodiments, the third layer may include a third layer aperture 340. In at least one embodiment of the present invention, the third layer aperture may be aligned, at least partially, with at least one of the aperture and the opening. The third layer aperture may serve as a conduit for allowing the light from the light source 215 to at least partially pass through the third layer to the ambient environment. Suitable shapes for the third layer aperture include, but are not limited to, an apple, a circle, a square, an emoticon, a corporate approved logo, user-submitted design, any conceivable shape(s) and a combination thereof

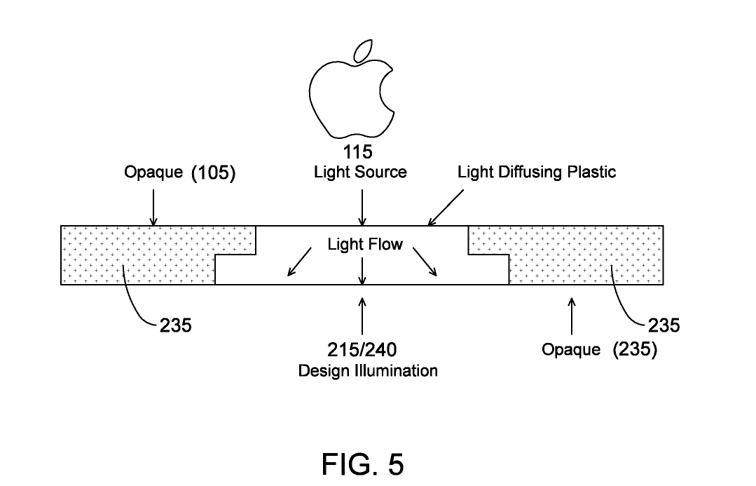

FIG. 5 illustrates a diagram of an exemplary light source passing through an exemplary first layer aperture, in accordance with an embodiment of the present invention. Those skilled in the art, in light of the present teachings, will recognize that the three layers may create a synergy between each other to manipulate the light from the light source. In this manner, the functional and decorative aspects of the electronic device may be enhanced. In some embodiments, at least one of the first layer 205, the second layer 235, and the third layer may include a lens. In at least one embodiment of the present invention, the lens may be disposed in at least one of the first layer 205, the second layer 235, and the third layer The lens may be configured to make the light diverge in some embodiments. In other embodiments, the lens may be configured to make the light converge. In at least one embodiment of the present invention, at least one of the first layer 205, the second layer 235, and the third layer may include a screen. The screen may be disposed in at least one of the first layer 205, the second layer 235, and the third layer in some embodiments. Suitable types of screens include, but are not limited to, an LCD screen, a plasma screen, a LED screen. In some embodiments, at least one of the first layer 205, the second layer 235, and the third layer may include a prism. In at least one embodiment of the present invention, the prism may be configured to split light from the light source 215, which originated from the electronic device. In some embodiments, the prism may be configured to transmit the split light through the screen. The screen may display an image on at least one of the ambient environment, the first layer 205, the second layer 235, and the third layer in some embodiments. In some embodiments, at least one of the first layer 205, the second layer 235, and the third layer may include an optical fiber. In at least one embodiment of the present invention, the optical fiber may be configured to transmit light through at least one of, the first layer, the aperture, the second layer, the opening, the third layer, and the orifice, to the ambient environment. In some embodiments, the optical fiber may be configured to alter the color of the light.

In some embodiments, the light source may be controlled, at least partially, by software. The software may be installed on the electronic device to which the cover is joined in some embodiments. In at least one embodiment of the present invention, the software may be installed on a different electronic device. In some embodiments, the software may be installed on a portable storage device configured to plug into the electronic device. At least one of the screen, and the optical fiber may be powered by the electronic device in some embodiments. A portion of the cover 200 may be powered by the electronic device 210 by plugging into a port located on the electronic device. Suitable ports include, but are not limited to, a usb port, firewire, thunderbolt port, solar or battery power. In some embodiments, the software may be configured to randomly select a color or image to display. In at least one embodiment of the present invention, the software may be configured to have a user select a color or image to display. In some embodiments, a user may use the software to indicate a state including, but not limited to, a relationship status, an emotion, that the user has a question, that the user knows an answer, and a combination thereof. Those skilled in the art, in light of the present teachings, will recognize that changing the “status” signal of the cover is to enable more social behavior without having to speak up. The intention is to spark conversation, or gain attention for a person watching for a changed status.

Those skilled in the art will readily recognize, in light of and in accordance with the teachings of the present invention, that any of the foregoing steps and/or system modules may be suitably replaced, reordered, removed and additional steps and/or system modules may be inserted depending upon the needs of the particular application, and that the systems of the foregoing embodiments may be implemented using any of a wide variety of suitable processes and system modules, and is not limited to any particular computer hardware, software, middleware, firmware, microcode and the like. For any method steps described in the present application that can be carried out on a computing machine, a typical computer system can, when appropriately configured or designed, serve as a computer system in which those aspects of the invention may be embodied.

All the features or embodiment components disclosed in this specification, including any accompanying abstract and drawings, unless expressly stated otherwise, may be replaced by alternative features or components serving the same, equivalent or similar purpose as known by those skilled in the art to achieve the same, equivalent, suitable, or similar results by such alternative feature(s) or component(s) providing a similar function by virtue of their having known suitable properties for the intended purpose. Thus, unless expressly stated otherwise, each feature disclosed is one example only of a generic series of equivalent, or suitable, or similar features known or knowable to those skilled in the art without requiring undue experimentation.

Having fully described at least one embodiment of the present invention, other equivalent or alternative methods of implementing covers according to the present invention will be apparent to those skilled in the art. The invention has been described above by way of illustration, and the specific embodiments disclosed are not intended to limit the invention to the particular forms disclosed. The particular implementation of the cover may vary depending upon the particular context or application. By way of example, and not limitation, the covers described in the foregoing were principally directed to electronic device cover implementations; however, similar techniques may instead be applied to other devices with an external light source, including but not limited to, flashlights, headlights, and taillights, which implementations of the present invention are contemplated as within the scope of the present invention. The invention is thus to cover all modifications, equivalents, and alternatives falling within the spirit and scope of the following claims.

Claim elements and steps herein may have been numbered and/or lettered solely as an aid in readability and understanding. Any such numbering and lettering in itself is not intended to and should not be taken to indicate the ordering of elements and/or steps in the claims.

What is claimed is:

1. An electronic device cover comprising:
a first layer, said first layer being configured to cover an electronic device, said electronic device comprising a light source, said light source being operable to transmit a light, said first layer comprising a first layer mounting surface, said first layer mounting surface being configured to engage said electronic device, said first layer further comprising a first dimension, said first dimension being configured to substantially match the dimensions of the electronic device, said first layer further comprising a second dimension, said second dimension being configured to substantially match the dimensions of the electronic device; said first layer further comprising a first layer aperture, said first layer aperture being configured to allow said light from said light source to pass through said first layer;
a second layer, said second layer being configured to cover said first layer, said second layer comprising a second layer mounting surface, said second layer mounting surface being configured to engage said first layer, said second layer further comprising a second layer aperture, said second layer aperture being configured to allow said light from said light source to pass through said second layer; and
a third layer, said third layer being configured to cover said second layer, said third layer comprising a third layer mounting surface, said third layer mounting surface being configured to engage said second layer, said third layer further comprising a third layer aperture, said third layer aperture being configured to allow said light from said light source to pass through said third layer.

2. The electronic device cover of claim 1, wherein said first layer comprises a sufficiently translucent material to allow a passive light to at least partially pass through said first layer.

3. The electronic device cover of claim 2, in which said second layer and said third layer comprise an opaque material.

4. The electronic device cover of claim 3, wherein said first layer aperture is sufficiently transparent to allow a substantial amount of an active light to pass through said first layer.

5. The electronic device cover of claim 4, wherein said first layer aperture is shaped and dimensioned similarly to said light source.

6. The electronic device cover of claim 5, wherein said first layer aperture is configured to alter a color of said light from said light source.

7. The electronic device cover of claim 6, in which said first layer is fabricated from a plastic injected molding.

8. The electronic device cover of claim 7, in which said first layer, said second layer, and/or said third layer comprise different materials.

9. The electronic device cover of claim 8, in which said first layer, said second layer, and/or said third layer comprise a lens, said lens being operable to transmit and refract said light.

10. The electronic device cover of claim 9, in which said first layer, said second layer, and/or said third layer comprise a screen, said screen being operable to display an image.

11. The electronic device cover of claim 10, in which said first layer, said second layer, and/or said third layer comprise a prism, said prism being operable to break said light up into a multiplicity of spectral colors.

12. The electronic device cover of claim 11, in which said first layer, said second layer, and/or said third layer comprise an optical fiber, said optical fiber being operable to transmit said light from said light source to said first layer, said second layer, and/or said third layer.

13. The electronic device cover of claim 12, wherein said optical fiber is further operable to alter the color of said light.

14. The electronic device cover of claim 13, in which said electronic device comprises software, said software being operable to control said light source.

15. The electronic device cover of claim 14, in which said first layer, said second layer, and/or said third layer comprise an independent power source.

16. The electronic device cover of claim 15, wherein said independent power source generates an illumination.

17. The electronic device cover of claim 16, in which said electronic device comprises a laptop.

18. The electronic device cover of claim 17, in which said electronic device cover comprises a multiplicity of layers.

19. A method of covering an electronic device with an electronic device cover comprising:
means for orienting said electronic device for receiving said electronic device cover;
means for fastening a first layer to said electronic device;
means for passing a light from a light source in said electronic device through said first layer;
means for fastening a second layer to said first layer; and
means for fastening a third layer to said second layer.

20. An electronic device cover consisting of:
a first layer, said first layer being configured to cover an electronic device, said electronic device comprising a laptop computer, said electronic device further comprising a light source, said light source being operable to transmit a light, said first layer comprising a first layer mounting surface, said first layer mounting surface being configured to engage said electronic device, said first layer further comprising a first dimension, said first dimension being configured to substantially match the dimensions of the electronic device, said first layer further comprising a second dimension, said second dimension being configured to substantially match the dimensions of the electronic device; said first layer further comprising a first layer aperture, said first layer aperture being configured to allow said light from said light source to pass through said first layer, said first layer further comprising a lens, said lens being operable to transmit and refract said light, said first layer further comprising a screen, said screen being operable to display an image, said first layer further comprising a prism, said prism being operable to break said light up into a multiplicity of spectral colors, said first layer further comprising an optical fiber, said optical fiber being operable to transmit said light from said light source to said first layer;
a second layer, said second layer being configured to cover said first layer, said second layer comprising a second layer mounting surface, said second layer mounting surface being configured to engage said first layer, said second layer further comprising a second layer aperture, said second layer aperture being configured to allow said light from said light source to pass through said second layer, said second layer further comprising a lens, said lens being operable to transmit and refract said light, said second layer further comprising a screen, said screen being operable to display an image, said second layer further comprising a prism, said prism being operable to break said light up into a multiplicity of spectral colors, said second layer further comprising an optical fiber, said optical fiber being operable to transmit said light from said light source to said second layer; and
a third layer, said third layer being configured to cover said second layer, said third layer comprising a third layer mounting surface, said third layer mounting surface being configured to engage said second layer, said third layer further comprising a third layer aperture, said third layer aperture being configured to allow said light from said light source to pass through said third layer, said third layer further comprising a lens, said lens being operable to transmit and refract said light, said third layer further comprising a screen, said screen being operable to display an image, said third layer further comprising a prism, said prism being operable to break said light up into a multiplicity of spectral colors, said third layer further comprising an optical fiber, said optical fiber being operable to transmit said light from said light source to said third layer.
